(19) United States
(12) Patent Application Publication
(10) Pub. No.: US 2014/0160833 A1
(43) Pub. Date: Jun. 12, 2014

(54) SEMICONDUCTOR MEMORY DEVICE

(71) Applicant: PANASONIC CORPORATION, Osaka (JP)

(72) Inventors: Kunisato YAMAOKA, Osaka (JP); Hiroyasu NAGAI, Osaka (JP)

(73) Assignee: PANASONIC CORPORATION, Osaka (JP)

(21) Appl. No.: 14/182,730

(22) Filed: Feb. 18, 2014

Related U.S. Application Data
(63) Continuation of application No. PCT/JP2012/004998, filed on Aug. 7, 2012.

(30) Foreign Application Priority Data
Aug. 24, 2011 (JP) 2011-182276

(51) Int. Cl. G11C 13/00

(52) U.S. Cl. CPC G11C 13/004
USPC 365/148

(57) ABSTRACT

A semiconductor memory device includes a memory cell array, a plurality of reference cell arrays, a plurality of word lines, a plurality of bit lines, a plurality of reference word lines, a plurality of reference bit lines each being provided for an associated one of the reference cell arrays, and equalizing transistors each of which is provided between the plurality of reference bit lines and receives an associated one of independent control signals, and a potential of one of the plurality of reference bit lines and a plurality of one of the plurality of bit lines are input to a sense amplifier.

### CROSS-REFERENCE TO RELATED APPLICATION

This is a continuation of International Application No. PCT/JP2012/004998 filed on Aug. 7, 2012, which claims priority to Japanese Patent Application No. 2011-182276 filed on Aug. 24, 2011. The entire disclosures of these applications are incorporated by reference herein.

### BACKGROUND

The present disclosure relates to semiconductor memory devices, and more particularly to a technology for generating a reference current using reference cells each including a resistance changing element.

Types of semiconductor memory devices include volatile memories which require a power supply source for holding data and non-volatile memories which do not require a power supply source for holding data. Currently, flash memories are mainstream non-volatile memories but, in recent years, in view of demands for reduction in power consumption and increase in operation speed, the development of resistive random access memory (ReRAM) using a resistance changing element has been progressed.

In a ReRAM, when data piece stored in a memory cell is read out, a reference current used as a reference in determining data is generated by a reference cell, and a potential difference between the potential of the data piece read out from the memory cell and a potential (a reference potential which occurs in a variable resistance element) corresponding to the magnitude of the reference current is amplified by a sense amplifier. Then, whether or not the read-out data is “0” or “1” is determined on the basis of the amplification result.

FIG. 8 is a circuit diagram illustrating a configuration of a known semiconductor memory device (see, for example, Japanese Unexamined Patent Publication No. 2005-92912). The semiconductor memory device has a configuration in which one of a plurality of reference cells 14 is selected and a reference potential which occurs in a resistance changing element of the selected reference cell and a potential which occurs in a resistance changing element 1 of a memory cell 3 are compared to each other by a sense amplifier 12. In the semiconductor memory device of FIG. 8, when a data read-out operation is performed, only a gate RD of a reference cell selection circuit 18 is selected, and when a verifying operation is performed, only a gate RT1 or a gate TR2 is selected. Thus, the reference potential corresponding to an operation is input to the sense amplifier 12.

### SUMMARY

The above-described semiconductor memory device generates a reference current for a read-out operation or a verifying operation using only a single reference cell, and is not configured to equalize the reference current, and therefore, the generated reference current greatly varies.

In contrast, there are semiconductor memory device in which the reference potential is equalized using a plurality of reference cells (see, for example, Japanese Unexamined Patent Publication No. 2004-362720), as in a semiconductor memory device illustrated in FIG. 9. The semiconductor memory device is not a ReRAM and uses 1T1C ferroelectric memory cells as memory cells 101-104 and reference cells 121 and 122. Then, a reference potential that is input from each reference cell to a corresponding sense amplifier is equalized by changing, to the H level, an equalizing control signal REFEQ that is to be commonly input to each reference cell.

However, the semiconductor memory device of FIG. 9 is configured such that, when the equalizing control signal REFEQ is changed to the H level, all of the reference cells collectively equalize the reference potential. Thus, when a failure bit is included in one of the reference cells, the potential which occurs in a normal reference cell is influenced by the failure bit. As a result, there might be cases where a desired reference potential cannot be obtained and the yield is reduced.

In view of the foregoing, it is an object of the present invention to enable generation of a reference current with high accuracy even when there is a failure bit in a reference cell in a resistance changing type semiconductor memory device.

In order to achieve the above-described object, the present disclosure provides the following solution. For example, a semiconductor memory device according to an aspect of the present disclosure includes a memory cell array including a plurality of memory cells which are arranged in a matrix and each include a resistance chancing element, a plurality of reference cell arrays each including a plurality of reference cells which are arranged in a matrix and each include a resistance changing element, the plurality of reference cell arrays being arranged in line in a row direction of the memory cell array, a plurality of word lines each being provided for an associated one of rows of the memory cell array and commonly connected to multiple ones of the plurality of memory cells arranged in the associated row, a plurality of bit lines each being provided for an associated one of columns of the memory cell array and commonly connected to multiple ones of the plurality of memory cells arranged in the associated column, a plurality of reference word lines each being provided for an associated one of rows of the plurality of reference cell arrays and commonly connected to multiple ones of the plurality of reference cells arranged in the associated one of the rows of the plurality of reference cell arrays, a plurality of reference bit lines each being provided for an associated one of the plurality of reference cell arrays so as to extend in a column direction and commonly connected to multiple ones of the plurality of reference cells included in the associated reference cell array, and a plurality of equalizing transistors each being provided between the plurality of reference bit lines and configured to receive an associated one of independent control signals supplied to a gate thereof. The semiconductor memory device is configured such that a potential of one of the plurality of reference bit lines and a potential of one of the plurality of bit lines are input to a sense amplifier.

Thus, each of the reference cell arrays includes the plurality of reference cells, and therefore, the potentials of the reference bit lines which correspond to each reference cell array are equalized by multiple ones of the plurality of reference cells which are connected to the selected reference word line. That is, the accuracy of a reference current output to each reference bit line is higher than the accuracy of a reference current generated using a single reference cell.

Also, each of the equalizing transistors provided between the reference bit lines which correspond to each reference cell array is conduction-controlled by an associated one of independent control signals. Therefore, equalization of a reference current using a necessary reference cell array is allowed, and thus, adjustment of a reference current is enabled. Also, equalization using a plurality of reference cell arrays is allowed, and thus, the accuracy of a reference current may be further increased.

For example, when there is a reference cell array including a failure bit, only the equalizing transistor connected to the reference bit line which corresponds to the reference cell array is turned off, and thus, equalization using the reference cell array which corresponds to the reference bit line connected to the equalizing transistor which is on-controlled is allowed. That is, even when there is a failure bit, the accuracy of a reference current is not degraded.

The above-described semiconductor memory device may include a selection circuit to which at least two of the plurality of reference bit lines are connected and which is configured to select one of the reference bit lines connected thereto in accordance with a given selection signal and to connect the selected reference bit line to the sense amplifier.

Thus, the reference bit line connected to the selection circuit is selectively connected to the sense amplifier in accordance with the selection signal. For example, when the semiconductor memory device performs a first operation, a first reference bit line is connected to the sense amplifier and, when the semiconductor memory device performs a second operation, a second reference bit line is connected to the sense amplifier. Then, in the first and second operations, each equalizing transistor is on- and off-controlled such that different reference bit lines are connected to the first and second reference bit lines.

Thus, when the semiconductor memory device performs the first operation, a reference current necessary for the first operation is output to the first reference bit line and, when the semiconductor memory device performs the second operation, a reference current necessary for the second operation is output to the second reference bit line. Therefore, a reference cell array exclusively used for generating a reference current necessary for each operation does not have to be provided. That is, generation of a reference current necessary for each operation is enabled without increasing the circuit area of the semiconductor memory device.

According to the present disclosure, in a resistance changing type semiconductor memory device, a reference current with reduced variation and high accuracy may be generated even when there is a failure bit in a reference cell.

### BRIEF DESCRIPTION OF THE DRAWINGS

FIG. 1 is a circuit diagram of a semiconductor memory device according to a first embodiment.

FIG. 2 is a timing chart illustrating an example of the operation of the semiconductor memory device of FIG. 1.

FIG. 3 is a timing chart illustrating another example of the operation of the semiconductor memory device of FIG. 1.

FIG. 4 is a timing chart illustrating still another example of the operation of the semiconductor memory device of FIG. 1.

FIG. 5 is a circuit diagram of a semiconductor memory device according to a second embodiment.

FIG. 6 is a timing chart illustrating an example of the operation of the semiconductor memory device of FIG. 5.

FIG. 7 is a circuit diagram of a modified example of the semiconductor memory device of FIG. 1.

FIG. 8 is a circuit diagram of a known semiconductor memory device.

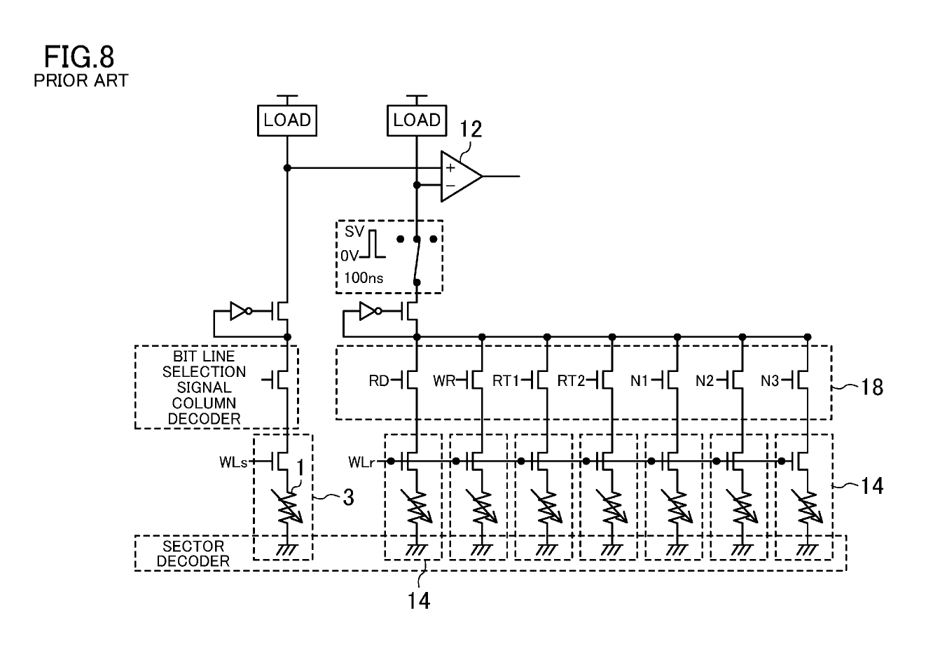

FIG. 9 is a circuit diagram of another known semiconductor memory device.

### DETAILED DESCRIPTION

### First Embodiment

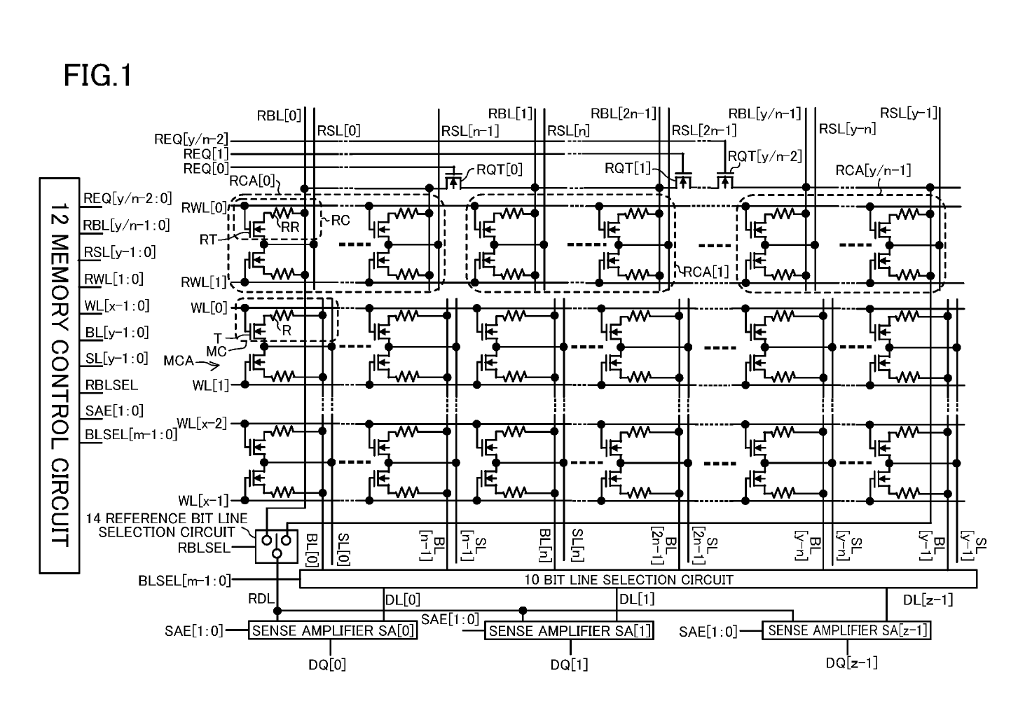

FIG. 1 is a circuit diagram of a semiconductor memory device according to a first embodiment. The semiconductor memory device is a resistance changing type nonvolatile memory device and includes a memory cell array MCA, a plurality of bit lines BL[0]-BL[y−1] (which will be hereinafter abbreviated to “BL” as appropriate), a plurality of source lines SL[0]-SL[y−1] (which will be hereinafter abbreviated to “SL” as appropriate), a plurality of word lines WL[0]-WL[x−1] (which will be hereinafter abbreviated to “WL” as appropriate), a bit line selection circuit 10, a plurality of sense amplifiers SA[0]-SA[z−1] (which will be hereinafter abbreviated to “SA” as appropriate), a memory control circuit 12, a plurality of reference cell arrays RCA[0]-RCA[y/n−1] (which will be hereinafter abbreviated to “RCA” as appropriate), a plurality of reference bit lines RBL[0]-RBL[y/n−1] (which will be hereinafter abbreviated to “RBL” as appropriate), a plurality of reference source lines RSL[0]-RSL[y−1] (which will be hereinafter abbreviated to “RSL” as appropriate), a plurality of reference word lines RWL[0] and RWL[1] (which will be hereinafter abbreviated to “RWL” as appropriate), equalizing transistors RQT[0]-RQT[y/n−2] (which will be hereinafter abbreviated to “RQT” as appropriate), and a reference bit line selection circuit 14.

The memory cell array MCA includes a plurality of memory cells MC arranged in a matrix of x rows×y columns, y bit lines BL, y source lines SL, and x word lines WL.

Each of the memory cells MC is, for example, a 1T1R memory cell and includes a resistance changing element R and a transistor T whose drain is connected to one end of the resistance changing element R.

Each of the bit lines BL is provided for an associated one of the columns of the memory cell array MCA. Each of the bit lines BL commonly connects the respective other ends of the resistance changing elements R of the memory cells MC arranged in the same column A wire layer for the bit lines BL may be arbitrarily determined, but it is preferable that the bit lines BL are disposed in the same wire layer.

Each of the source lines SL is provided for an associated one of the columns of the memory cell array MCA. Each of the source lines SL commonly connects respective sources of the transistors T of the memory cells MC arranged in the same column A wire layer for the source lines SL may be arbitrarily determined, but it is preferable that the source lines SL are disposed in the same wire layer.

Each of the word lines WL is provided for an associated one of the rows of the memory cell array MCA. Each of the word lines WL commonly connects respective gates of the transistors T of the memory cells MC arranged in the same row.

The reference cell arrays RCA are arranged in line in the row direction of the memory cell array MCA. For example, the reference cell arrays RCA are arranged so as to be adjacent to a side in the upper side in FIG. 1 as a side extending in the row direction of the memory cell array MCA. Each of the reference cell arrays RCA includes plurality of reference cells RC arranged, for example, in a matrix of two rows×n columns, two reference word lines RWL[0] and RWL[1], a single reference bit line RBL, and a plurality of reference source lines RSL.

Each of the reference cells RC generates a reference current used as a reference in determining data read out from the corresponding memory cell MC and includes a resistance changing element RR and a transistor RT whose drain is connected to one end of the resistance changing element RR.

Each of the reference bit lines RBL is provided for an associated one of the reference cell arrays RCA so as to extend in the column direction. The reference bit line RBL commonly connects the respective other ends of the resistance changing elements RR of the reference cells RC included in the corresponding reference cell array RCA. A wire layer for the reference bit lines RBL may be arbitrarily determined, but it is preferable that the reference bit lines RBL are disposed in the same wire layer. Also, the reference bit lines RBL and the bit lines BL may be disposed in the same wire layer.

Each of the reference source lines RSL is provided for an associated one of the columns of the reference cell arrays RCA. Each of the reference source lines RSL commonly connects respective sources of the transistors RT of the reference cells RC arranged in the same column. A wire layer for the reference source lines RSL may be arbitrarily determined, but it is preferable that the reference source lines RSL are disposed in the same wire layer. Also, the reference source lines RSL and the source lines SL may be disposed in the same wire layer.

Each of the reference word lines RWL is provided for an associated one of the rows of the reference cell arrays RCA. Each of the reference word lines RWL commonly connects respective gates of the transistors RT of the reference cells RC arranged in the same row of the each of the reference cell arrays RCA.

Equalizing transistor RQT are provided such that each of the equalizing transistor RQT is located between each of the reference bit lines RBL and an adjacent one thereto. For example, a drain of the equalizing transistor RQT[0] is connected to the reference bit line RBL[0], and a source of the equalizing transistor RQT[0] is connected to the reference bit line RBL[1]. For the other equalizing transistors RQT, their drains and sources are connected in the same manner. Then, each of equalizing signals REQ[0]-REQ[y/n−2] (which will be hereinafter abbreviated to “REQ” as appropriate), which are independent control signals, is supplied to the gate of an associated one of the equalizing transistors RQT. For example, the equalizing transistor RQT turns on, when the signal REQ is at the H level, and turns off, when the signal REQ is at the L level. With the above-described configuration, any one of equalizing transistors RQT can be turned on and off. Note that the drain of the equalizing transistor RQT[0] may be connected to the reference bit line RBL[1] while the source of the equalizing transistor RQT[0] may be connected to the reference bit line RBL[0].

The bit line selection circuit 10 selects z bit lines BL of the y bit lines BL in accordance with a bit line selection signal BLSEL[m−1:0] and connects each of the selected bit lines BL to an associated one of the wires DL[0]-DL[z−1] (which will be hereinafter abbreviated to “DL” as appropriate). Each of the wires DL is connected to one terminal of an associated one of the sense amplifiers SA.

The reference bit line selection circuit 14 selectively connects two of the reference bit lines RBL to a wire RDL in accordance with a selection signal RBLSEL. The wire RDL is connected to the other terminal of each of the sense amplifiers SA. According to this embodiment, for example, the reference bit line selection circuit 14 is configured such that, when the signal RBLSEL is at the H level, the reference bit line RBL[0] is selected and, when the signal RBLSEL is at the L level, the reference bit line RBL[y/n−1] is selected. Note that the reference bit line selection circuit 14 may be configured to connect one of three or more reference bit lines RBL to an associated one of the sense amplifiers SA. In this case, the signal RBLSEL is a signal of a plurality of bits. Also, it is preferable that at least one of a wiring capacity and a wiring resistance is set to be the same for the reference bit lines RBL connected to the reference bit line selection circuit 14.

Each of the sense amplifiers SA is started, when receiving a sense amplifier starting signal SAE[1:0], to amplify a potential difference between the potential of the wire RDL and the potential of an associated one of the wires DL. Then, as a result of the amplification, the sense amplifier SA outputs data pieces DQ[0]-DQ[z−1].

The memory control circuit 12 includes a circuit, such as a word driver, and the like, and outputs various types of signals each indicating the H level or the L level to the above-described components.

Next, as the operation of the semiconductor memory device according to this embodiment, a verifying operation and a read-out operation will be hereinafter described. For describing each operation, it is hereinafter assumed that the resistance changing element RR of each of the reference cells RC disposed in positions relatively close to the reference bit line RBL[0] is in a low resistance state and the resistance changing element RR of each of the reference cells RC disposed in positions relatively close to the reference bit line RBL[y/n−1] is in a high resistance state.

Specifically, it is assumed that n=8 and x=y=64, the resistance changing element RR of each of the reference cells RC included in the reference cell arrays RCA[0]-RCA[3] is in a low resistance state, and the resistance changing element RR of each of the reference cells RC included in the reference cell arrays RCA[4]-RCA[7] is in a high resistance state. Also, it is assumed that the bit line BL[0] and the wire DL[0] are connected to each other by the bit line selection circuit 10.

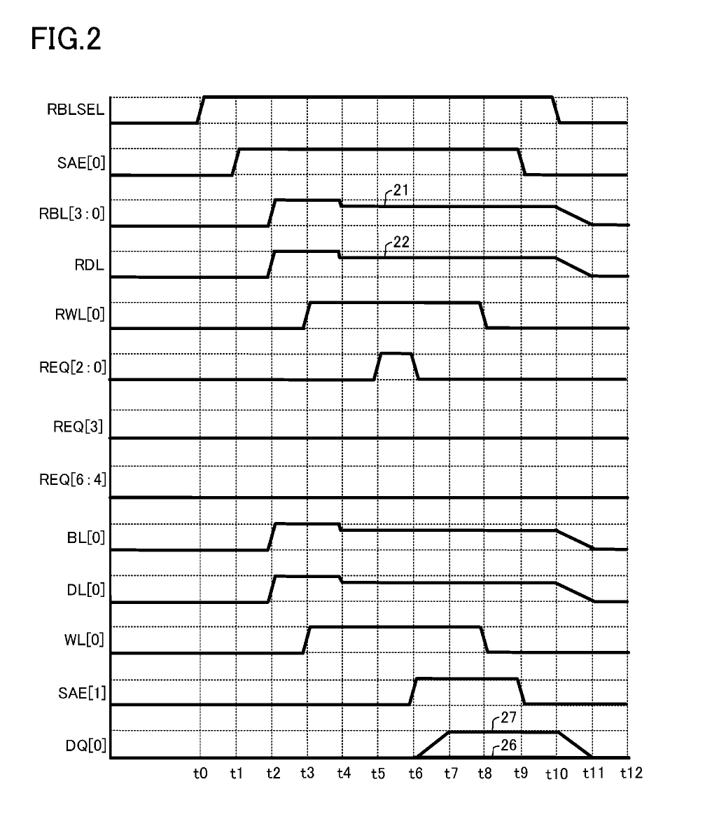

FIG. 2 is a timing chart illustrating the verifying operation performed when the resistance changing element R of the memory cell MC surrounded by a dashed line is caused to be in a low resistance state in the semiconductor memory device of FIG. 1. Each reference character commonly used in FIG. 1 and FIG. 2 indicates the same signal or the same wire.

First, at the time t0, the signal RBLSEL is changed to the H level to cause the reference bit line selection circuit 14 to select the reference bit line RBL[0]. Thus, the wire RDL and the reference bit line RBL[0] are connected to each other.

When the signal SAE[0] is changed to the H level at the time t1, the sense amplifier SA[0] is started, and thus, at the time t2, the wire RDL and the wire DL[0] are precharged, for example, to the H level as a predetermined potential. Accordingly, the potentials of the reference bit line RBL[0] and the bit line BL[0] vary in the same manner.

When, at the time t3, the potentials of the word line WL[0] and the reference word line RWL[0] are changed to the H level to cause them to be in a selected state, data pieces stored in the memory cell MC and the reference cell RC included in the reference cell array RCA[0] are read out. The resistance changing element RR of the reference cell RC is in a low resistance state, and therefore, the potential of the reference bit line RBL[0] is slightly reduced between the time t3 and the time t4. Thus, the potential of the wire RDL varies in the same manner. Also, if the resistance changing element R of the memory cell MC is in a low resistance state, the potential of the bit line BL[0] is slightly reduced between the time t3 and the time t4, and accordingly, the potential of the wire DL[0] varies in the same manner.

Then, when the signal REQ[2:0] is changed to the H level at the time t5, the equalizing transistors RQT[0]-RQT[2] are turned on, and therefore, the reference bit lines RBL[0]-RBL[3] are electrically connected. Thus, at and after the time t5, the potentials of the reference bit lines RBL[0]-RBL[3] are equalized, and each of the potentials has a waveform indicated by the reference character 21. Accordingly, the potential of the wire RDL varies in the same manner to have a waveform indicated by the reference character 22. Note that, the signals REQ[3]-REQ[6] are kept at the L level at all the time during the entire verifying operation.

When the signal SAE[1] is changed to the H level at the time t6, the sense amplifier SA[0] amplifies a potential difference between the potential of the wire RDL and the potential of the wire DL[0]. At this point of time, if the potential of the wire DL[0] is lower than the potential of the wire RDL, data DQ[0] has a waveform of L data, as indicated by the reference character 26. That is, the resistance changing element R of the memory cell MC is not in a low resistance state.

On the other hand, if the potential of the wire DL[0] is higher than the potential of the wire RDL, data DQ[0] has a waveform of H data, as indicated by the reference character 27. That is, the resistance changing element R of the memory cell MC is in a low resistance state.

At the time t8, the potentials of the word line WL[0] and the reference word line RWL[0] are changed to the L level to cause them to be in a non-selected state.

Then, when the signals SAE[0] and SAE[1] are changed to the L level at the time t9, and thereafter, the signal RBLSEL is changed to the L level at the time t10, the respective potentials of the reference bit lines RBL[0]-RBL[3], the wire RDL, the bit line BL[0], and the wire DL[0], and the data DQ[0] are changed to the L level.

As described above, assuming a period from the time t0 to the time t12 as a one cycle, the verifying operation in which the resistance changing element R of the memory cell MC is caused to be in a low resistance state is repeated until the waveform indicated by the reference character 27 appears on the waveform of the data DQ[0].

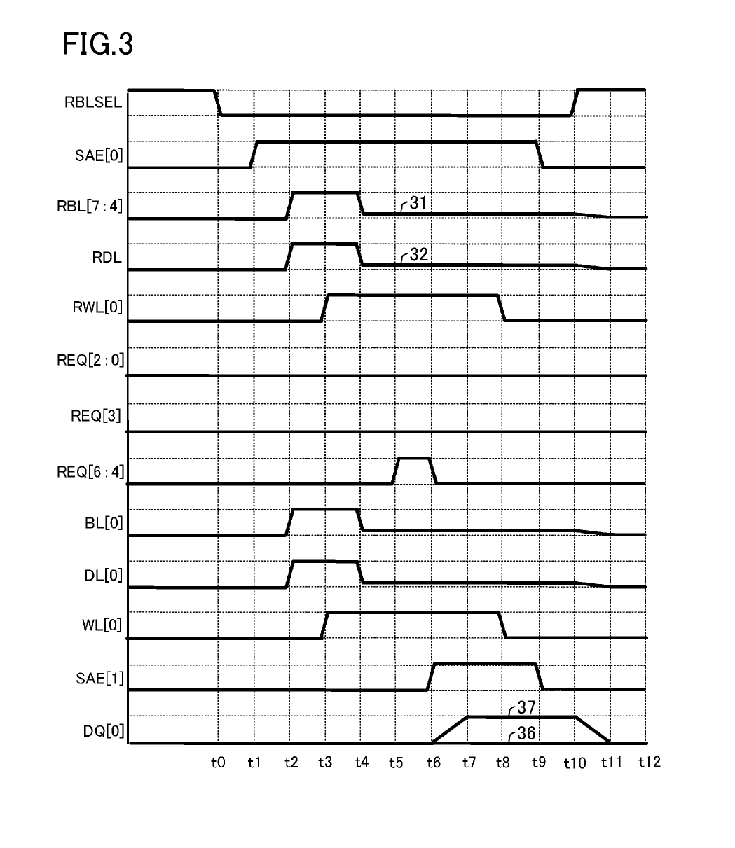

Next, another operation of the semiconductor memory device according to this embodiment will be described. FIG. 3 is a timing chart illustrating a verifying operation performed when the resistance changing element R of the memory cell MC surrounded by a dashed line illustrated in FIG. 1 is caused to be in a high resistance state. Note that each reference character commonly used in FIG. 2 and FIG. 3 indicates the same signal or the same wire.

First, at the time t0, the signal RBLSEL is changed to the L level to cause the reference bit line selection circuit 14 to select the reference bit line RBL[7]. Thus, the wire RDL and the reference bit line RBL[7] are connected to each other.

When the signal SAE[0] is changed to the H level at the time t1, the sense amplifier SA[0] is started, and thus, at the time t2, the wire RDL and the wire DL[0], and the reference bit lines RBL[7] and the bit line BL[0] which are connected to the wire RDL and the wire DL[0], respectively, are precharged, for example, to the H level as a predetermined potential.

When, at the time t3, the potentials of the word line WL[0] and the reference word line RWL[0] are changed to the H level to cause them to be in a selected state, data pieces stored in the memory cell MC and the reference cell RC included in the reference cell array RCA[7] are read out. The resistance changing element RR of the reference cell RC is in a high resistance state, and therefore, the potential of the reference bit line RBL[7] is greatly reduced, as compared to the case of FIG. 2, between the time t3 and the time t4. Thus, the potential of the wire RDL varies in the same manner. Also, if the resistance changing element R of the memory cell MC is in a high resistance state, the potential of the bit line BL[0] is greatly reduced, as compared to the case of FIG. 2, between the time t3 and the time t4, and accordingly, the potential of the wire DL[0] varies in the same manner.

Then, when the signal REQ[6:4] is changed to the H level at the time t5, the equalizing transistors RQT[4]-RQT[6] are turned on, and therefore, the reference bit lines RBL[4]-RBL[7] are electrically connected. Thus, at and after the time t5, the potentials of the reference bit lines RBL[4]-RBL[7] are equalized, and the potentials each have a waveform indicated by the reference character 31. Accordingly, the potential of the wire RDL varies in the same manner to have a waveform indicated by the reference character 32. Note that, the signals REQ[0]-REQ[3] are kept at the L level at all the time during the entire verifying operation.

When the signal SAE[1] is changed to the H level at the time t6, the sense amplifier SA[0] amplifies a potential difference between the potential of the wire RDL and the potential of the wire DL[0]. At this point of time, if the potential of the wire DL[0] is lower than the potential of the wire RDL, data DQ[0] has a waveform of L data, as indicated by the reference character 36. That is, the resistance changing element R of the memory cell MC is in a high resistance state.

On the other hand, if the potential of the wire DL[0] is higher than the potential of the wire RDL, data DQ[0] has a waveform of H data, as indicated by the reference character 37. That is, the resistance changing element R of the memory cell MC is not in a high resistance state.

At the time t8, the potentials of the word line WL[0] and the reference word line RWL[0] are changed to the L level to cause them to be in a non-selected state.

Then, when the signals SAE[0] and SAE[1] are changed to the L level at the time t9, and thereafter, the signal RBLSEL is changed to the H level at the time t10, the respective potentials of the reference bit lines RBL[4]-RBL[7], the wire RDL, the bit line BL[0], and the wire DL[0], and the data DQ[0] are caused to be at the L level.

As described above, assuming a period from the time t0 to the time t12 as a one cycle, the verifying operation in which the resistance changing element R of the memory cell MC is caused to be in a high resistance state is repeated until the waveform indicated by the reference character 36 appears on the waveform of the data DQ[0].

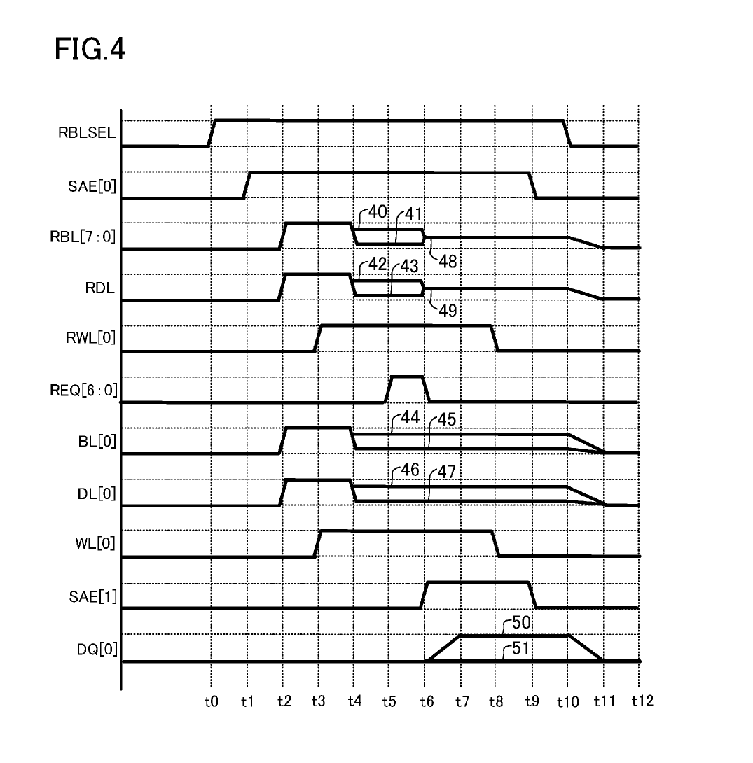

Next, still another operation of the semiconductor memory device according to this embodiment will be described. FIG. 4 is a timing chart illustrating an operation performed when a data piece stored in the memory cell MC surrounded by a dashed line illustrated in FIG. 1 is read out. Note that it is assumed that the resistance changing element R of the memory cell MC is in a low resistance state.

First, at the time t0, the signal RBLSEL is changed to the H level to cause the reference bit line selection circuit 14 to select the reference bit line RBL[0]. Thus, the wire RDL and the reference bit line RBL[0] are connected to each other.

When the signal SAE[0] is changed to the H level at the time t1, the sense amplifier SA[0] is started, and thus, at the time t2, the wire RDL and the wire DL[0], and the reference bit lines RBL[0] and the bit line BL[0] which are connected to the wire RDL and the wire DL[0], respectively, are precharged, for example, to the H level as a predetermined potential.

When, at the time t3, the potentials of the word line WL[0] and the reference word line RWL[0] are changed to the H level to cause them to be in a selected state, data pieces stored in the memory cell MC and the reference cell RC included in the reference cell array RCA[0] are read out. In this case, the resistance changing elements RR in the reference cell arrays RCA[0]-RCA[3] are in a low resistance state, and therefore, the potentials of the reference bit lines RBL[0]-RBL[3] each have a waveform indicated by the reference character 40. On the other hand, the resistance changing elements RR in the reference cell arrays RCA[4]-RCA[7] are in a high resistance state, and therefore, the potentials of the reference bit lines RBL[4]-RBL[7] each have a waveform indicated by the reference character 41. Also, the potential of the wire RDL varies in the same manner as the potential of the reference bit line RBL[0]. That is, the potential of the wire RDL has a waveform indicated by the reference character 42. Note that, if the wire RDL and the reference bit line RBL[7] are connected to each other by the reference bit line selection circuit 14, the potential of the wire RDL has a waveform indicated by the reference character 43.

The resistance changing element R of the memory cell MC is in a low resistance state, and therefore, the potential of the bit line BL[0] has a waveform indicated by the reference character 44. Accordingly, the potential of the wire DL[0] varies in the same manner to have a waveform indicated by the reference character 46. Note that, if the resistance changing element R of the memory cell MC is in a high resistance state, the potential of the bit line BL[0] has a waveform indicated by the reference character 45. Accordingly, the potential of the wire DL[0] has a waveform indicated by the reference character 47.

When the signal REQ[6:0] is changed to the H level at the time t5, the equalizing transistors RQT[0]-RQT[6] are turned on, and therefore, the reference bit lines RBL[0]-RBL[7] are electrically connected. Thus, at and after the time t5, the potentials of the reference bit lines RBL[0]-RBL[7] are equalized, and the potentials each have a waveform indicated by the reference character 48. Accordingly, the potential of the wire RDL has a waveform indicated by the reference character 49.

When the signal SAE[1] is changed to the H level at the time t6, the sense amplifier SA[0] amplifies a potential difference between the potential of the wire RDL and the potential of the wire DL[0]. In this case, the resistance changing element R of the memory cell MC is in a low resistance state, and therefore, the potential of the wire DL[0] is higher than the potential of the wire RDL. Accordingly, data DQ[0] has a waveform indicated by the reference character 50. That is, H data has been read out from the memory cell MC. On the other hand, if the resistance changing element R of the memory cell MC is in a high resistance state and the potential of the wire DL[0] is lower than the potential of the wire RDL, the data DQ[0] has a waveform indicated by the reference character 51, that is, L data has been read out.

At the time t8, the potentials of the word line WL[0] and the reference word line RWL[0] are changed to the L level to cause them to be in a non-selected state.

Then, when the signals SAE[0] and SAE[1] are changed to the L level at the time t9, and thereafter, the signal RBLSEL is changed to the L level at the time t10, the respective potentials of the reference bit lines RBL[1]-RBL[7], the bit line BL[0], and the wire DL[0], and the data DQ[0] are caused to be at the L level.

As described above, according to this embodiment, each of the reference cell arrays RCA includes the plurality of reference cells RC and a reference current is equalized using the plurality of reference cells RC, and thus, as compared to the case where a reference current is generated by a single reference cell, variation in reference current may be reduced and the accuracy thereof may be increased. Also, equalization using the plurality of reference cell arrays RCA is allowed, and thus, generation of a reference current with higher accuracy is enabled.

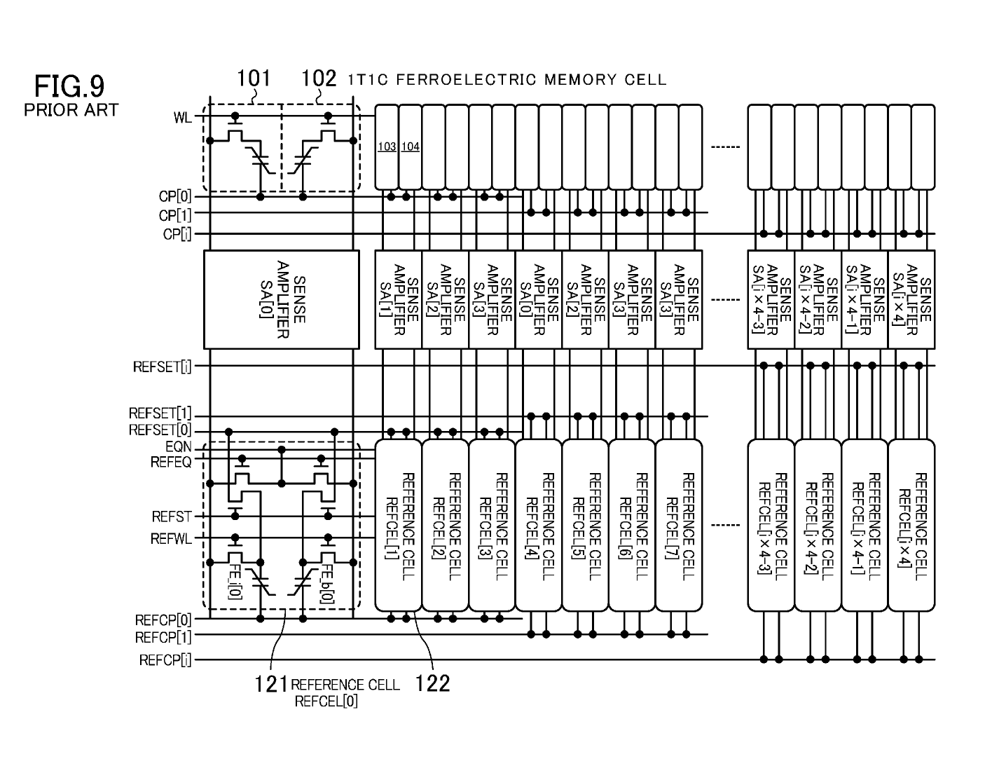

In order to achieve the accuracy of a reference level necessary for each of the two types of verifying operations and the read-out operation, which have been described above, equalization using a plurality of reference cells of predetermined bits or more is required. In this case, in the semiconductor memory device of FIG. 9, a plurality of reference cells of predetermined bits or more for generating a reference level with the accuracy necessary for each operation has to be provided. For example, three rows of the plurality of reference cells arranged in the left-and-right direction (the row direction) in FIG. 9 are necessary. This is because, in the configuration illustrated in FIG. 9, the respective potentials of the reference bit lines are collectively equalized in accordance with the equalizing control signal REFEQ commonly supplied to the plurality of reference cells and thus only one reference level can be generated by equalization using the plurality of reference cells. Therefore, if each of the above-described operations is to be performed with the configuration illustrated in FIG. 9, the circuit area of the semiconductor memory device is increased.

In contrast, according to this embodiment, as illustrated in FIG. 1, reference currents for the two types of verifying operations and a reference current for a read-out operation may be generated by a single row of the reference cell arrays RCA, and thus, the circuit area is not increased.

Also, the equalizing transistor RQT can be individually on- and off-controlled by the signal REQ, and thus, adjustment of a reference current may be performed.

For example, when a failure bit is included in the reference cell array RCA[3], the signal REQ[2] is changed to the L level and the signals REQ[0] and REQ[1] are changed to the H level to perform equalization. Thus, the influence of the failure bit of the reference cell array RCA[3] on the reference cell arrays RCA[0]-RCA[2] can be ignored. That is, even when there is a failure bit in the reference cell arrays RCA, a desired and highly accurate reference current may be obtained.

Note that the equalizing transistor RQT may connect two reference bit lines RBL, and therefore, for example, an equalizing transistor RQT configured to connect the reference bit lines RBL[0] and RBL[2] to each other may be provided.

Also, in the memory cell MC, one end of the resistance changing element R may be connected to the source line SL. In this case, the source of the transistor T may be connected to the other end of the resistance changing element R and the drain of the transistor T may be connected to the bit line BL. Similarly, the reference cell RC may be configured such that one end of the resistance changing element RR is connected to the reference source line RSL. In this case, the source of the transistor RT may be connected to the other end of the resistance changing element RR and the drain of the transistor RT may be connected to the reference bit line RBL.

### Second Embodiment

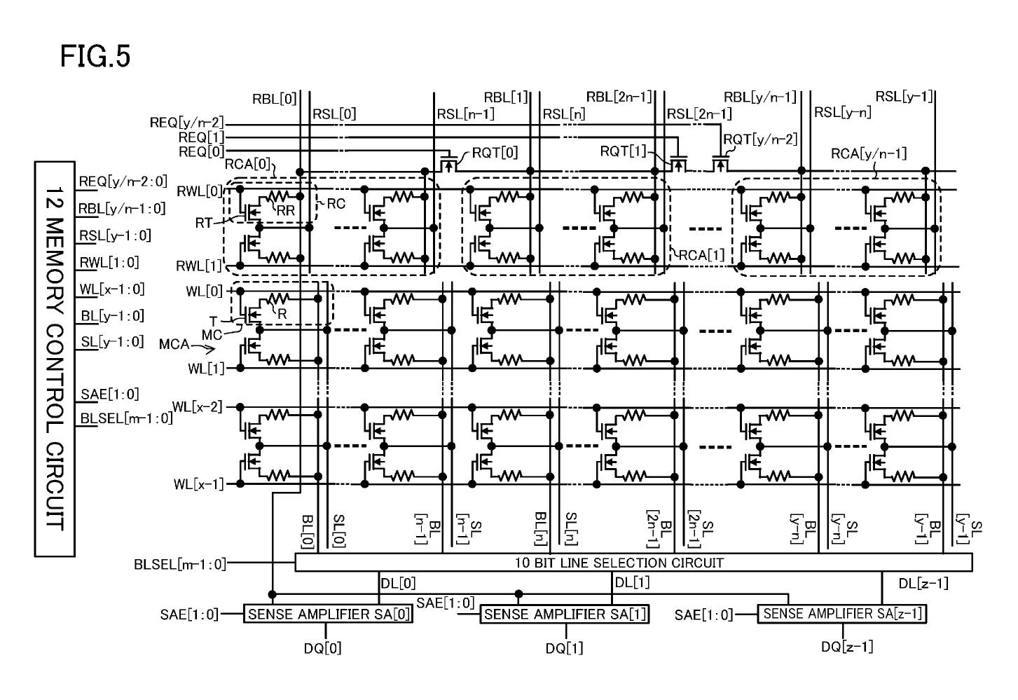

FIG. 5 is a circuit diagram of a semiconductor memory device according to a second embodiment. Each reference character commonly used in FIG. 1 and FIG. 5 indicates the same component, and therefore, the description thereof will be omitted. The semiconductor memory device of FIG. 5 is different from the semiconductor memory device of FIG. 1 in that the reference bit line selection circuit 14 and the wire RDL are omitted. Also, in the semiconductor memory device of FIG. 5, as one of the plurality of reference bit lines RBL, for example, the reference bit line RBL[0] and the bit line BL selected by the bit line selection circuit 10 are connected to the sense amplifier SA.

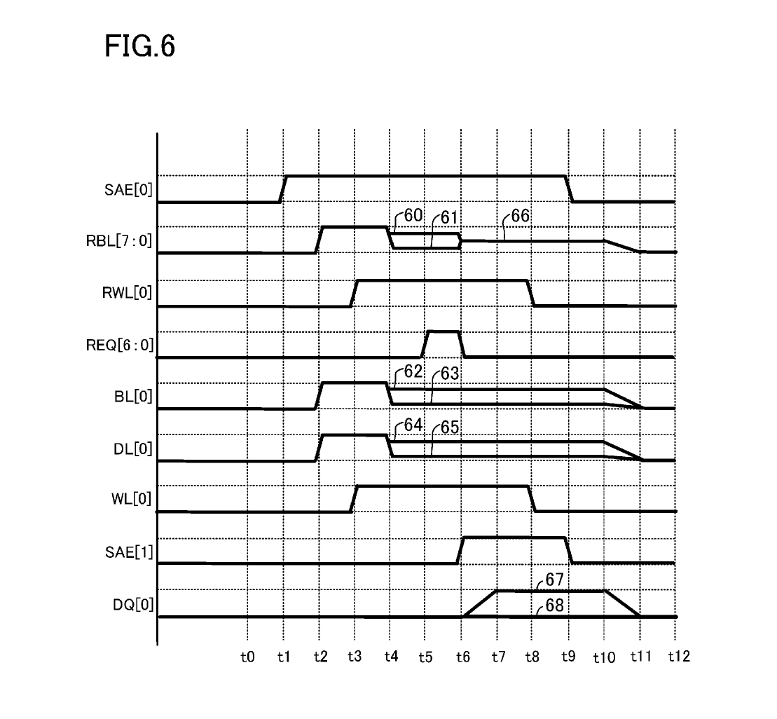

The operation of the semiconductor memory device according to this embodiment will be described. FIG. 6 is a timing chart illustrating an operation performed when a data piece stored in the memory cell MC surrounded by a dashed line illustrated in FIG. 5 is read out. Note that the values of n, x, and y and the states of the resistance changing elements RR of the reference cells RC, and the state of the resistance changing element R of the memory cell MC are the same as those in the case of the first embodiment. Also, it is assumed that the bit line BL[0] and the wire DL[0] are connected to each other by the bit line selection circuit 10.

When the signal SAE[0] is changed to the H level at the time t1, the sense amplifier SA[0] is started, and thus, at the time t2, the reference bit line RBL[0], the wire DL[0], and the bit line BL[0] connected to the wire DL[0] are precharged, for example, to the H level as a predetermined potential.

When, at the time t3, the potentials of the word line WL[0] and the reference word line RWL[0] are changed to the H level to cause them to be in a selected state, data pieces stored in the memory cell MC and the reference cell RC included in the reference cell array RCA[0] are read out. The resistance changing elements RR in the reference cell arrays RCA[0]-RCA[3] are in a low resistance state, and therefore, the potentials of the reference bit lines RBL[0]-RBL[3] each have a waveform indicated by the reference character 60. On the other hand, the resistance changing elements RR in the reference cell arrays RCA[4]-RCA[7] are in a high resistance state, and therefore, the potentials of the reference bit lines RBL[4]-RBL[7] each have a waveform indicated by the reference character 61.

The resistance changing element R of the memory cell MC is in a low resistance state, and therefore, the potential of the bit line BL[0] has a waveform indicated by the reference character 62. Accordingly, the potential of the wire DL[0] varies in the same manner to have a waveform indicated by the reference character 64. Note that, if the resistance changing element R of the memory cell MC is in a high resistance state, the potential of the bit line BL[0] has a waveform indicated by the reference character 63, and accordingly, the potential of the wire DL[0] has a waveform indicated by the reference character 65.

When the signal REQ[6:0] is changed to the H level at the time t5, the equalizing transistors RQT[0]-RQT[6] are turned on, and therefore, the reference bit lines RBL[0]-RBL[7] are electrically connected. Thus, at and after the time t5, the potentials of the reference bit lines RBL[0]-RBL[7] are equalized, and the potentials each have a waveform indicated by the reference character 66.

When the signal SAE[1] is changed to the H level at the time t6, the sense amplifier SA[0] amplifies a potential difference between the potential of the reference bit line RBL[0] and the potential of the wire DL[0]. In this case, the resistance changing element R of the memory cell MC is in a low resistance state, and therefore, the potential of the wire DL[0] is higher than the potential of the reference bit line RBL[0]. Accordingly, data DQ[0] has a waveform indicated by the reference character 67. That is, H data has been read out from the memory cell MC. On the other hand, if the resistance changing element R of the memory cell MC is in a high resistance state and the potential of the wire DL[0] is lower than the potential of the reference bit line RBL[0], the data DQ[0] has a waveform indicated by the reference character 68, that is, L data has been read out.

At the time t8, the potentials of the word line WL[0] and the reference word line RWL[0] are changed to the L level to cause them to be in a non-selected state.

Then, at the time t9, the signals SAE[0] and SAE[1] are changed to the L level, and thereafter, the respective potentials of the reference bit lines RBL[0]-RBL[7], the wire RDL, the bit line BL[0], and the wire DQ[0], and the data DQ[0] are caused to be at the L level.

As described above, according to this embodiment, the potentials of the reference bit lines RBL are equalized using the plurality of reference cell arrays RCA, and therefore, a reference current for a read-out operation with reduced variation and high accuracy may be generated. Also, only a necessary equalizing transistor RQT is on-controlled, and thus, adjustment of a reference current is enabled.

Note that, in each of the above-described embodiments, each of the memory cells MC and the reference cells RC may be configured to include a diode and a resistance changing element. In this case, the source lines SL and the reference source lines RSL are not needed.

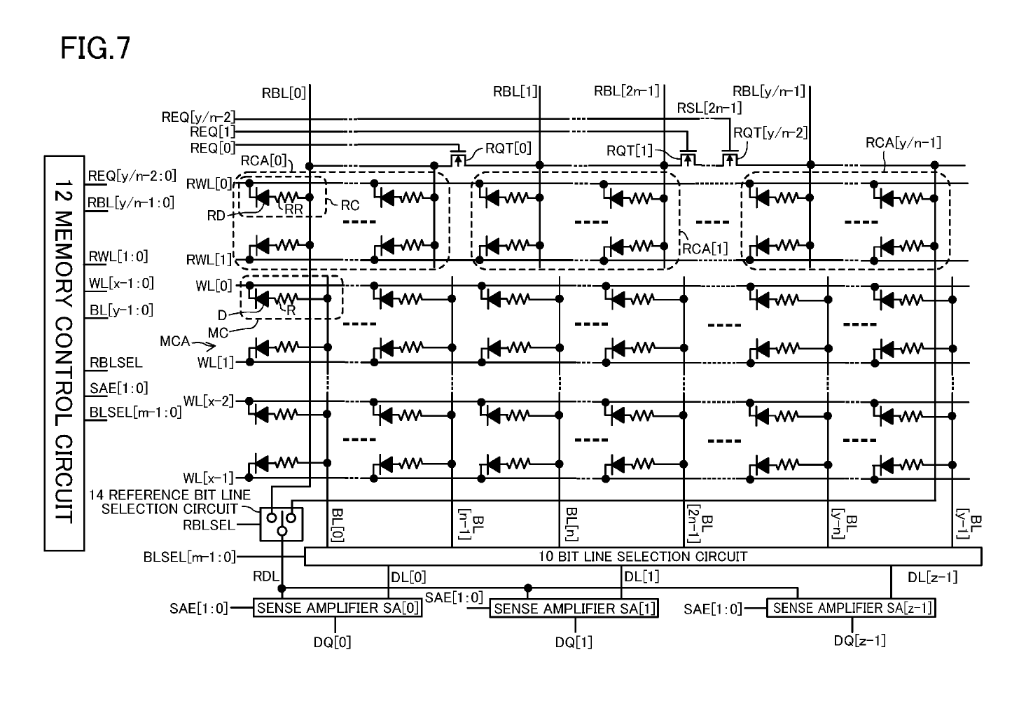

Specifically, as illustrated in FIG. 7, each of the memory cells MC may include a diode D and a resistance changing element R. In this case, an anode of the diode D may be connected to the resistance changing element R and a cathode of the diode D may be connected to an associated one of the word lines WL.

Also, each of the reference cells RC may include a diode RD and a resistance changing element RR. In this case, an anode of the diode RD may be connected to the resistance changing element RR and a cathode of the diode RD may be connected to an associated one of the reference word line RWL.

Also, in the above-described semiconductor memory device, the plurality of reference word lines RWL may be collectively driven. Thus, the transistor RT of each of the reference cells RC included in the reference cell arrays RCA is selected, and therefore, the equalizing effect is increased.

Also, in the above-described semiconductor memory device, an arbitrary arrangement interval may be set for the memory cells MC and the reference cells RC, but it is preferable that the memory cells MC and the reference cells RC are laid out uniformly on a semiconductor substrate. For example, the memory cells MC and the reference cells RC may be arranged at a predetermined pitch in the row direction, and may be arranged at a predetermined pitch in the column direction. Furthermore, the memory cells MC and the reference cells RC may be arranged at a predetermined pitch both in the row direction and the column direction. Thus, the characteristics of the memory cells MC and the reference cells RC are equalized, and therefore, generation of a reference current with higher accuracy is enabled.

According to the present disclosure, the circuit area of a semiconductor memory device may be reduced, and also, a reference current with high accuracy may be generated. Therefore, the present disclosure is useful when miniaturization and increase in performance for semiconductor memory device are demanded.

What is claimed is:

1. A semiconductor memory device, comprising:
a memory cell array including a plurality of memory cells which are arranged in a matrix and each include a resistance chancing element;
a plurality of reference cell arrays each including a plurality of reference cells which are arranged in a matrix and each include a resistance changing element, the plurality of reference cell arrays being arranged in line in a row direction of the memory cell array;
a plurality of word lines each being provided for an associated one of rows of the memory cell array and commonly connected to multiple ones of the plurality of memory cells arranged in the associated row;
a plurality of bit lines each being provided for an associated one of columns of the memory cell array and commonly connected to multiple ones of the plurality of memory cells arranged in the associated column;
a plurality of reference word lines each being provided for an associated one of rows of the plurality of reference cell arrays and commonly connected to multiple ones of the plurality of reference cells arranged in the associated one of the rows of the plurality of reference cell arrays;
a plurality of reference bit lines each being provided for an associated one of the plurality of reference cell arrays so as to extend in a column direction and commonly connected to multiple ones of the plurality of reference cells included in the associated reference cell array; and
a plurality of equalizing transistors each being provided between the plurality of reference bit lines and configured to receive an associated one of independent control signals supplied to a gate thereof,
wherein
a potential of one of the plurality of reference bit lines and a potential of one of the plurality of bit lines are input to a sense amplifier.

2. The semiconductor memory device of claim 1, further comprising:
a selection circuit to which at least two of the plurality of reference bit lines are connected and which is configured to select one of the reference bit lines connected thereto in accordance with a given selection signal and to connect the selected reference bit line to the sense amplifier.

3. The semiconductor memory device of claim 1, wherein
the plurality of reference word lines is collectively driven.

4. The semiconductor memory device of claim 1, wherein
the plurality of bit lines is arranged in a same wire layer.

5. The semiconductor memory device of claim 1, wherein
the plurality of reference bit lines is arranged in a same wire layer.

6. The semiconductor memory device of claim 1, wherein
the plurality of bit lines and the plurality of reference bit lines are arranged in a same wire layer.

7. The semiconductor memory device of claim 2, wherein
at least one of a wire capacity and a wire resistance is substantially a same for the reference bit lines connected to the selection circuit.

8. The semiconductor memory device of claim 1, further comprising:
a plurality of source lines each being provided for an associated one of the columns of the memory cell array and commonly connected to multiple ones of the plurality of memory cells arranged in the associated column; and
a plurality of reference source lines each being provided for an associated one of the columns of the reference cell arrays and commonly connected to multiple ones of the plurality of reference cells arranged in the associated column,
wherein
each of the memory cells includes a transistor which is connected in series to a resistance changing element of the memory cell between one of the bit lines and one of the source lines which correspond to the memory cell, and whose gate is connected to one of the word lines which corresponds to the memory cell, and
the each of the reference cells includes a transistor which is connected in series to the resistance changing element of the reference cell between one of the reference bit lines which corresponds to one of the reference cell arrays which includes the reference cell and one of the reference source lines which corresponds to the reference cell, and whose gate is connected to one of the reference word lines which corresponds to the reference cell.

9. The semiconductor memory device of claim 8, wherein
the plurality of source lines is arranged in a same wire layer.

10. The semiconductor memory device of claim 8, wherein
the plurality of reference source lines is arranged in a same wire layer.

11. The semiconductor memory device of claim 8, wherein
the plurality of source lines and the plurality of reference source lines are arranged in a same wire layer.

12. The semiconductor memory device of claim 1, wherein
the reference cells included in the plurality of reference cell arrays and the memory cells included in the memory cell array are arranged at a predetermined pitch in at least one of the row direction and the column direction.

13. The semiconductor memory device of claim 1, wherein
each of the memory cells includes a diode whose anode is connected to the resistance change element connected to one of the bit lines which corresponds to the memory cell, and whose cathode is connected to one of the word lines which corresponds to the memory cell, and
each of the reference cells includes a diode whose anode is connected to the resistance changing element connected to one of the reference bit lines which corresponds to one of the reference cell arrays which includes the reference cell, and whose cathode is connected to one of the reference word lines which corresponds to the reference cell.
